(19) United States
(12) Patent Application Publication
(10) Pub. No.: US 2005/0093042 A1
(43) Pub. Date: May 5, 2005

(54) Semiconductor device and method of manufacturing the same

(76) Inventors: Keisuke Nakazawa, Tokyo (JP); Hiroyuki Kanaya, Yokohama-shi (JP); Atsuko Kawasaki, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/952,871

(22) Filed: Sep. 30, 2004

(30) Foreign Application Priority Data
Oct. 2, 2003 (JP) 2003-344651

(51) Int. Cl. H01L 29/76

(52) U.S. Cl. 257/295

(57) ABSTRACT

A semiconductor device comprises a semiconductor substrate, a plurality of capacitors provided above the semiconductor substrate and including a lower electrode, a ferroelectric film, and an upper electrode, and a polysilazane-based coated insulating film provided on the plurality of capacitors and between the plurality of capacitors and burying a gap between the plurality of capacitors.

### CROSS-REFERENCE TO RELATED APPLICATIONS

This application is based upon and claims the benefit of priority from prior Japanese Patent Application No. 2003-344651, filed Oct. 2, 2003, the entire contents of which are incorporated herein by reference.

### BACKGROUND OF THE INVENTION

1. Field of the Invention

The invention relates to a semiconductor device including a capacitor using a ferroelectric film as a capacitor insulating film and a method of manufacturing the same.

2. Description of the Related Art

FIG. 5 shows a sectional view of a capacitor of a conventional ferroelectric memory. Two capacitors 80 are shown in FIG. 5. The capacitor 80 includes a lower electrode 81 and a ferroelectric film 82 and an upper electrode 83.

When the ferroelectric film 82 comes into contact with a reducing atmosphere such as hydrogen gas, its electric characteristics deteriorate. A large amount of reducing gas is produced in the downstream process of a semiconductor process. In order to prevent the reducing gas from coming into the capacitor 80 from the outside, the capacitor 80 is covered with a barrier film 84. Further, the periphery of the barrier film 84 is completely covered with a silicon dioxide film (TEOS oxide film) 85 formed by a CVD method using tetraethoxysilane (TEOS). In FIG. 5, a reference numeral 86 denotes an insulating film, 87 denotes a plug, and 88 denotes a barrier film.

As the degree of integration or fine patterning of a ferroelectric memory of this kind is increased further, a distance Lcc between neighboring capacitors becomes shorter. When the distance Lcc becomes shorter, as shown in FIG. 6, a small gap 89 is produced in a valley between the neighboring capacitors 80, whereby the periphery of the capacitor 80 can not be completely buried with the TEOS oxide film 85.

The reducing gas comes into the TEOS oxide film 85 from the gap 89. The reducing gas coming into the TEOS oxide film 85 reaches the ferroelectric film 82. The reducing gas reaching the ferroelectric film 82 causes the deterioration of the electric characteristics of the ferroelectric film 82. As a result, this reduces the reliability of the ferroelectric memory.

Further, there are also cases where a silicon dioxide film formed by a coating method using a polysiloxane solution is used in place of the TEOS oxide film 85. In this case, since a volume shrinkage ratio when polysiloxane changes to silicon dioxide is large, there is produced a gap between the barrier film 84 and the silicon dioxide film. This gap causes the silicon dioxide film to peel off and the electric characteristics of the ferroelectric film 82 to be degraded by the reducing gas. Hence, even if the above-described silicon dioxide film is used, the reliability of the ferroelectric memory is reduced.

### BRIEF SUMMARY OF THE INVENTION

According to an aspect of the present invention, there is provided a semiconductor device comprising: a semiconductor substrate a plurality of capacitors provided above the semiconductor substrate and including a lower electrode, a ferroelectric film, and an upper electrode; and a polysilazane-based coated insulating film provided on the plurality of capacitors and between the plurality of capacitors and burying a gap between the plurality of capacitors.

According to an aspect of the present invention, there is provided a method of manufacturing a semiconductor device comprising: forming a first conductive film, a ferroelectric film, and a second conductive film above a semiconductor substrate in sequence; forming a plurality of capacitors by etching the second conductive film, the ferroelectric film, and the first conductive film, the plurality of capacitors comprising a plurality of upper electrodes each including the first conductive film, the ferroelectric film divided into a plurality of portions, and a plurality of lower electrodes each including the second conductive film; and forming a polysilazane-based coated insulating film on the plurality of capacitors and between the plurality of capacitors so as to bury a gap between the plurality of capacitors by a coating method using a solution containing polysilazane.

According to another aspect of the present invention, there is provided a method of manufacturing a semiconductor device: forming a plurality of lower electrodes above a semiconductor substrate; forming a ferroelectric film and a conductive film in sequence above the semiconductor substrate so as to cover top surfaces and side surfaces of the plurality of lower electrodes; forming a polysilazane-based coated insulating film on the conductive film so as to bury a gap between the plurality of lower electrodes by a coating method using a solution containing polysilazane; and forming a plurality of upper electrodes by etching the polysilazane-based coated insulating film and the conductive film.

### BRIEF DESCRIPTION OF THE SEVERAL VIEWS OF THE DRAWING

FIGS. 1A to 1H are cross sectional views showing a process of manufacturing a COP type ferroelectric memory cell according to a first embodiment of the present invention;

FIGS. 2A to 2E are cross sectional views showing a process of manufacturing a three-dimensional COP type ferroelectric memory cell according to a second embodiment of the present invention;

FIG. 3 is a cross sectional view showing a modification of the three-dimensional COP type ferroelectric memory cell of the second embodiment;

FIGS. 4A to 4B are equivalent circuit and cross sectional view of a series connected TC unit type ferroelectric RAM;

FIG. 5 is a cross sectional view showing a conventional ferroelectric memory; and

FIG. 6 is a cross sectional view illustrating a problem with a conventional ferroelectric memory.

### DETAILED DESCRIPTION OF THE INVENTION

Hereafter, embodiments of the present invention will be described with reference to the drawings.

### FIRST EMBODIMENT

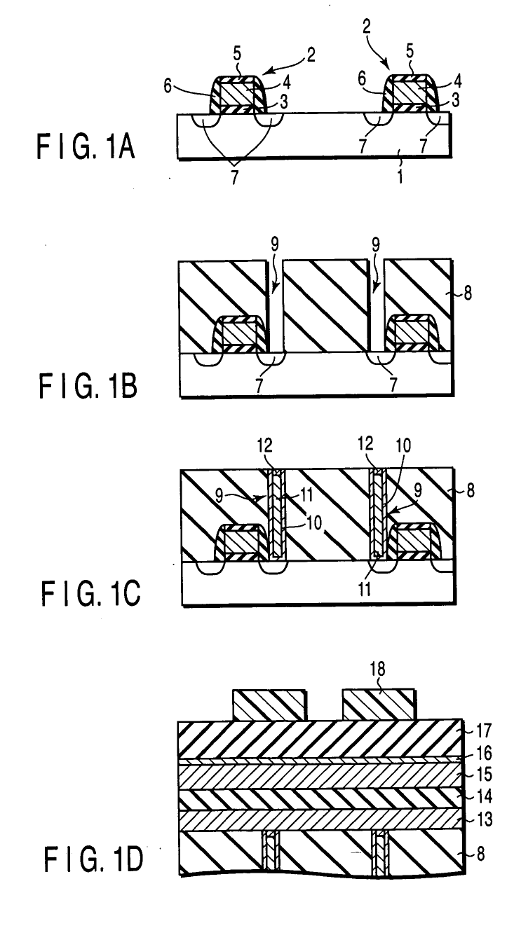

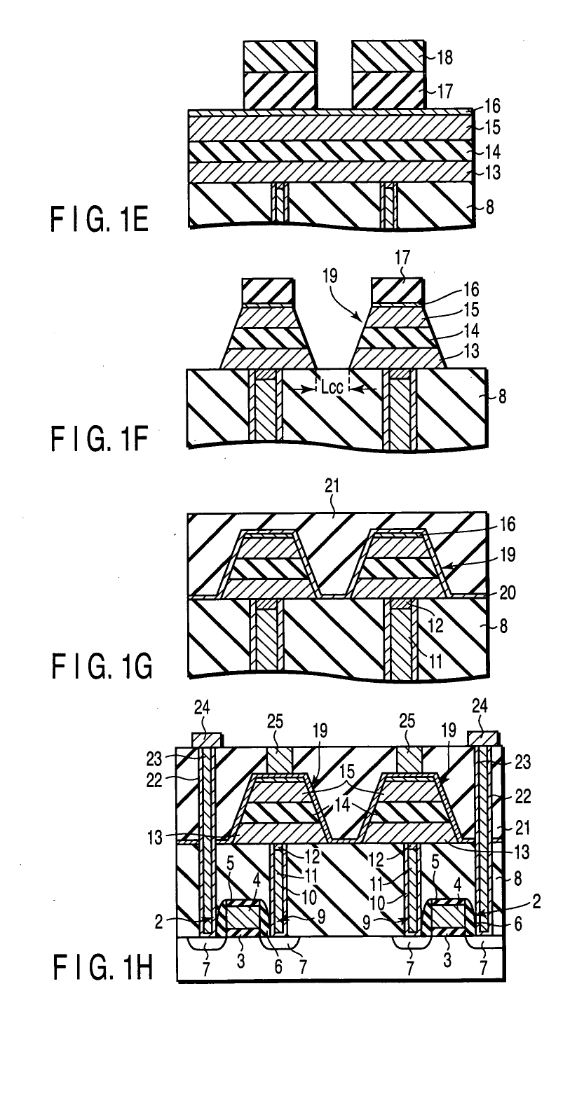

FIGS. 1A to 1G are sectional views to show a process of manufacturing a COP (capacitor on plug) type ferroelectric memory cell according to a first embodiment of the present invention.

First, as shown in FIG. 1A, a MOS transistor 2 for switching operation is formed on a silicon substrate 1 by a well-known method. The MOS transistor 2 includes a gate insulating film 3, a gate electrode 4, a gate upper insulating film 5, a gate side wall insulating film 6 and source/drain regions 7.

Next, as shown in FIG. 1B, a silicon oxide film is formed over the whole surface of the silicon substrate 1 by the CVD method and then the silicon oxide film is polished by a CMP (chemical mechanical polishing) method to form a silicon oxide film 8 having a flat surface and then a contact hole 9 reaching the source/drain region 7 connected to the lower electrode of the capacitor is formed in the silicon oxide film 8.

Next, as shown in FIG. 1C, the side surface and bottom surface of the contact hole 9 are covered with a barrier metal film 10 and thereafter a plug 11 and a barrier film 12 to prevent the oxidation of the plug 11 are formed in the contact hole 9.

The barrier metal film 10 is, for example, a TiN film and the plug 11 is, for example, a W plug, and the barrier film 12 is, for example, a TiAlN film, a TiN film, or a TaSiN film.

Next, as shown in FIG. 1D, the first conductive film 13 to be processed into a plurality of lower electrodes and a ferroelectric film (capacitor insulting film) 14 are formed and then are subjected to a heating treatment to crystallize the ferroelectric film 14.

As the first conductive film 13, for example, a noble metal film such as a Pt film, an Ir film, and a Pd film, or a conductive oxide film such as a SrRuO₃ film and an IrO₂ film, or a laminated film of these films (for example, Pt film/Ir film) can be used. As a method of forming the first conductive film 13, for example, a sputtering method or a MOCVD method can be used. The first conductive film 13 is formed in a film thickness of about 100 nm.

As the ferroelectric film 14, for example, a lead titanate zirconate (PZT) film, a strontium bismuth tantalate (SBT) film, a bismuth lanthanum titanate (BLT) film, or a bismuth titanate (BIT) film can be used.

As a method of forming the ferroelectric film 14, the sputtering method, the coating method, or the MOCVD method can be used. In a case where the ferroelectric film 14 is formed of a PZT film, a heating treatment to crystallize the ferroelectric film 14 is performed within a temperature range of from 500° C. to 700° C.

Next, as shown in FIG. 1D, the second conductive film 15 to be processed into a plurality of upper electrodes, a barrier film 16 having resistance to reduction, and a Silicon oxide film 17 to be processed into a hard mask are formed in sequence on the ferroelectric film 14 and thereafter a resist pattern 18 is formed on the Silicon oxide film 17. The silicon oxide film 17 is for example a TEOS oxide film.

A film to be used as the second conductive film 15, a method of forming the second conductive film 15, and a film thickness of the second conductive film 15 are same as those of the first conductive film 13.

As the barrier film 16, for example, an Al₂O₃ film can be used. As a method of forming the Al₂O₃ film, for example, a vapor deposition method can be used.

As a method of forming the Silicon oxide film 17, for example, a CVD method or the coating method can be used.

Next, as shown in FIG. 1E, the Silicon oxide film 17 is etched by using a resist pattern 18 as a mask. Thereafter, the resist pattern 18 is removed.

Next, as shown in FIG. 1F, the barrier film 16, the second conductive film 15, the ferroelectric film 14, and the first conductive film 13 are etched by a well-known RIE (reactive ion etching) process by using the above-described etched TEOS oxide film (hard mask) as a mask.

In this manner, a plurality of capacitors 19 can be produced each of which has the lower electrode 13, the ferroelectric film 14, the upper electrode 15 and the barrier film 16 laminated in sequence and has a tapered shape. The shape when viewed from above the upper electrode 15 is square or circular and has a side of from about 0.25 μm to 1 μm. The distance Lcc between the capacitors ranges from about 0.25 μm to 1 μm. It is acceptable to make the upper electrode and the Lcc larger or smaller than the above-described values. Thereafter, the hard mask 17 is removed. A process that the hard mask 17 is not removed can be performed. In this case, the hard mask 17 is covered with a barrier film 20 in the next step.

Next, as shown in FIG. 1G, the barrier film (for example, Al₂O₃ film) 20 is formed over the whole surface so as to cover the capacitor 19 and then a polysilazane film 21 containing a small amount of nitrogen is formed on the barrier film 16 so as to make the surface flat. The concentration of nitrogen in the polysilazane film 21 is 10% by weight or less.

In the conventional technology, when the Lcc becomes 1 μm or less, it is difficult to bury the gap between the capacitors with the TEOS oxide film and the gap 89 shown in FIG. 6 is produced in the TEOS oxide film. In particular, when the Lcc becomes 0.5 μm or less, the gap 89 is apt to be produced in the conventional technology.

However, when the gap between the capacitors is buried with the polysilazane film 21, even if the Lcc becomes 1 μm or less, in particular, 0.5 μm or less, the gap 89 shown in FIG. 6 is not produced. That is, according to the present embodiment, the gap produced between the neighboring capacitors can be completely buried with the polysilazane film 21.

The polysilazane film 21 is formed, for example, in the following manner. That is, a polysilazane solution is applied to the surface of the silicon substrate 1 by a rotary coating method and the polysilazane solution applied to the silicon substrate 1 is baked in a nitrogen gas atmosphere at 350° C. for 1 minute and then is subjected to a heat treatment (oxidation heat treatment) in an oxygen gas at a temperature from 550° C. to 700° C. for from 5 minutes to 30 minutes.

The polysilazane solution contains polysilazane (polymer) and carbon as well, so that the polysilazane film 21 contains carbon. It is clear from analysis that the polysilazane film 21 that is one kind of silicon dioxide film is different from a silicon dioxide film such as TEOS oxide film. As an analysis method, for example, a secondary ion mass spectrometry (SIMS) can be used.

In the present embodiment, the oxidation of the plug 11 is prevented by the barrier film 12, but as described above, the performing of the oxidation heat treatment at low temperatures can effectively prevent the oxidation of the plug 11.

The well-known steps are performed following the step shown in FIG. 1G. That is, as shown in FIG. 1H, a step of forming a via hole connected to the other source/drain region 7 in the polysilazane film 21 and the silicon oxide film 8, a step of forming a barrier metal film 22 and a plug 23 in the via hole, and a step of forming a bit line 24 electrically connected to the plug 23, and a step of forming a wiring 25 which is electrically connected to the upper electrode 15 and to which a driving pulse is applied follow the step shown in FIG. 1G.

In this manner, according to the present embodiment, a ferroelectric memory can be realized that includes: the plurality of MOS transistors 2 provided on the silicon substrate 1; the plurality of capacitors 19 provided above the silicon substrate 1 and including the lower electrode 13, the ferroelectric film 14 and the upper electrode 15; and the polysilazane film 21 formed on the plurality of capacitors 19 and between the plurality of capacitors 19 and for burying the gap between the neighboring capacitors 19 completely.

In this manner, according to the present embodiment, the gap produced between the neighboring capacitors 19 is completely buried with the polysilazane film 21, so that the deterioration of the ferroelectric film 14 by the reducing gas such as hydrogen gas can be prevented, which results in improving the reliability of the ferroelectric memory.

### SECOND EMBODIMENT

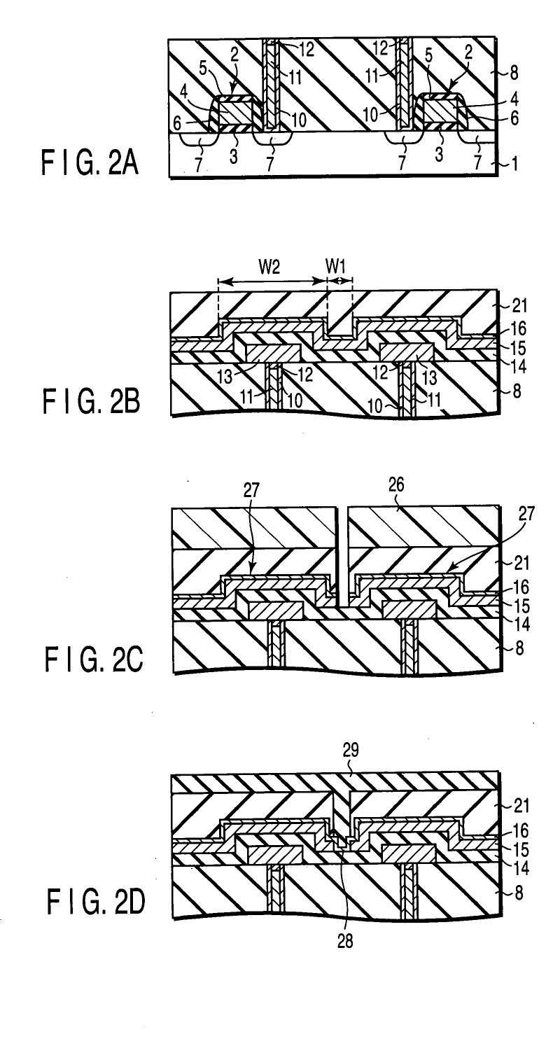

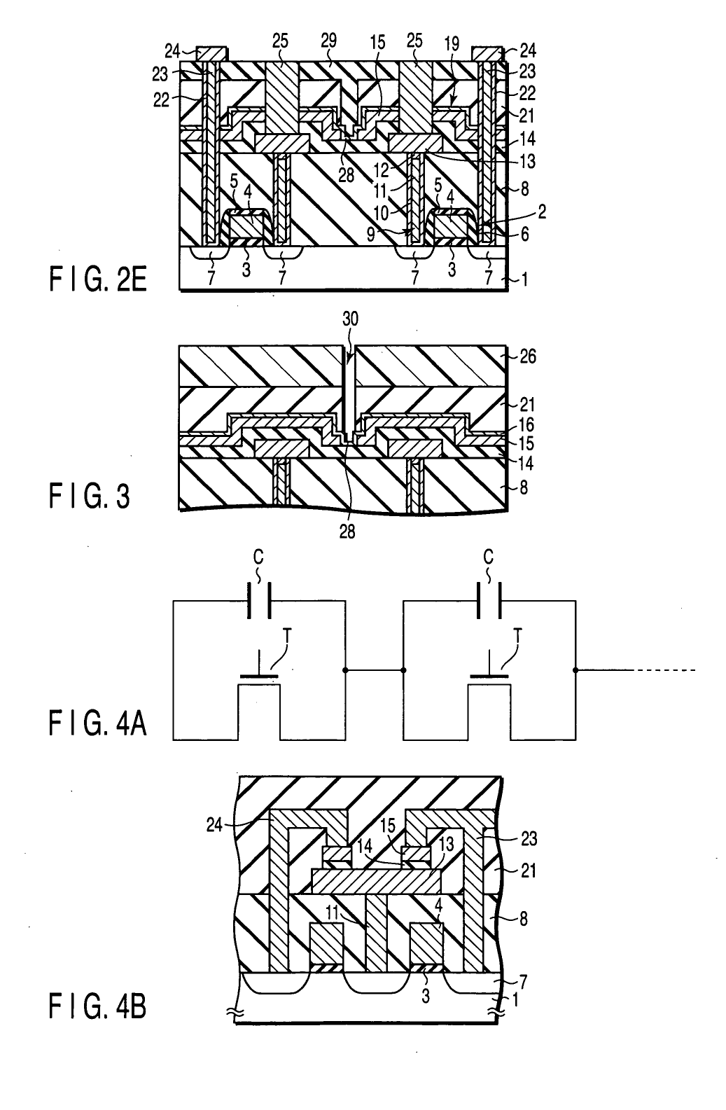

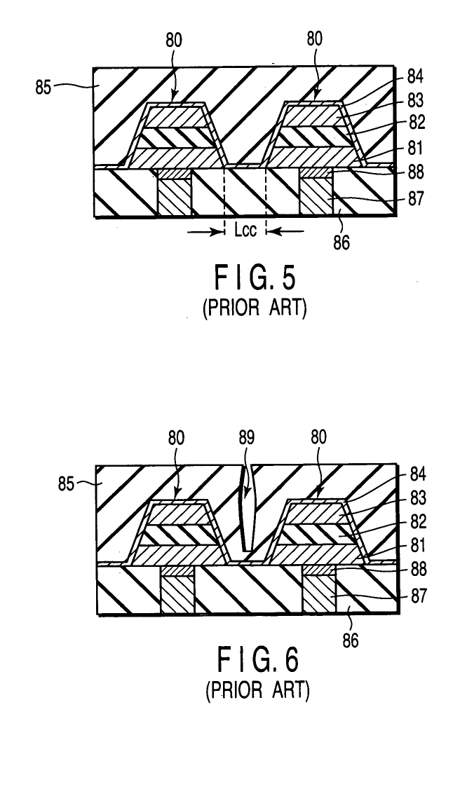

FIGS. 2A to 2E are sectional views to show a process of manufacturing a three-dimensional COP type ferroelectric memory cell according to the second embodiment of the present invention. Here, parts corresponding to those in FIGS. 1A to 1H are denoted by the same reference numerals and their detailed descriptions will be omitted.

FIG. 2A shows a sectional view at a stage where the steps up to the step shown in FIG. 1C of the first embodiment are finished.

Following the step of FIG. 2A, as shown in FIG. 2B, the lower electrode 13 is formed so as to be electrically connected to the plug 11 and then the ferroelectric film 14 having a thickness of about 100 nm is formed over the whole surface of the lower. electrode 13 so as to cover the side surface and top surface of the lower electrode 13 by the MOCVD method and then a heating treatment for crystallizing the ferroelectric film 14 is performed.

Next, as shown in FIG. 2B, the second conductive film 15 to be processed into an upper electrode and has a thickness of about 100 nm is formed on the ferroelectric film 14 by the MOCVD method and then. the barrier film 16 is formed on the second conductive film 15.

While the conductive film described in the first embodiment can be used as the second conductive film 15, among them, the Ir film or the IrO₂ film easily formed by the MOCVD method can be preferably used.

As the barrier film 16, for example, an Al₂O₃ film is used. The film thickness of the Al₂O₃ film is, for example, 50 nm. An ALD (atomic layered deposition) method can be preferably used as a method of forming an Al₂O₃ film. This is because the ALD method can easily form the barrier film 16 having a uniform film thickness on the second conductive film 15 having projection portions and depression portions on the surface.

In the present embodiment, the width W1 of the depression portion is from about 0.25 μm to 1 μm and the width W2 (length of one side of a square) of the projection portion is from about 0.25 μm to 1 μm. The shape of the projection portion when viewed from above is square or circular. It is acceptable to make the widths W1 and W2 smaller or larger than the value described above.

Next, as shown in FIG. 2B, the polysilazane film 21 containing a small amount of nitrogen is formed on the barrier film 16 so as to make the surface flat. The concrete method of forming the polysilazane film 21 is such that has been described in the first embodiment.

Next, as shown in FIG. 2C, a resist pattern 26 having openings above the depression portions are formed on the polysilazane film 21 and then the polysilazane film 21, the barrier film 16, the second conductive film 15 are etched by using the resist pattern 26 as a mask to separate these films 21, 16 and 15. As a result, a plurality of three-dimensional capacitors 27 can be produced.

The well-known steps follow the step in FIG. 2C. That is, as shown in FIG. 2D, a step of forming a barrier film 28, a step of removing the resist pattern 26, a step of forming a polysilazane film 29, and then as is the case with the first embodiment, as shown in FIG. 2E, a step of forming the barrier metal film 22, a step of forming the plug 23, a step of forming the bit line 24, and a step of forming the wiring 25 follow the step in FIG. 2C.

Here, in the step shown in FIG. 2D, as shown in FIG. 3, it is acceptable to form the barrier film 28 up to a position higher than the barrier film 16 exposed to the side wall surface of the opening 30.

In this manner, according to the present embodiment, a ferroelectric memory can be realized that includes: the plurality of MOS transistors 2 formed on the silicon substrate 1; the plurality of capacitors 27 formed above the silicon substrate 1 and including the lower electrode 13, the ferroelectric film 14 and the upper electrode 15; and the polysilazane films 21 and 29 formed on the plurality of capacitors 27 and between the plurality of capacitors and for burying the gap between the neighboring capacitors 19 completely.

Further, also in the present embodiment, because of the same reason as in the first embodiment, the deterioration of the ferroelectric film 14 by the reducing gas such as hydrogen gas can be prevented, which results in improving the reliability of the ferroelectric memory.

In this regard, the present invention is not limited to the above-described embodiments but, for example, the present invention can be applied to a ferroelectric memory (Series connected TC unit type ferroelectric RAM) shown in FIG. 4A. The ferroelectric memory comprises series connected memory cell each having a transistor having a source terminal and a drain terminal and a ferroelectric capacitor between the two terminals. FIG. 4B shows a sectional view of a cell structure shown in FIG. 4A.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device comprising:
a semiconductor substrate;
a plurality of capacitors provided above the semiconductor substrate and including a lower electrode, a ferroelectric film, and an upper electrode; and
a polysilazane-based coated insulating film provided on the plurality of capacitors and between the plurality of capacitors and burying a gap between the plurality of capacitors.

2. The semiconductor device according to claim 1, wherein the polysilazane-based coated insulating film contains nitrogen.

3. The semiconductor device according to claim 1, wherein the polysilazane-based coated insulating film contains carbon.

4. The semiconductor device according to claim 1, wherein the plurality of capacitors has a 1 μm or less distance between neighboring capacitors.

5. The semiconductor device according to claim 4, wherein the plurality of capacitors has a 0.5 μm or less distance between neighboring capacitors.

6. The semiconductor device according to claim 1, further comprising a barrier film provided between each of the plurality of capacitors and the polysilazane-based coated insulating film and having resistance to reduction.

7. The semiconductor device according to claim 6, wherein the plurality of capacitors has a 0.5 μm or less distance between neighboring capacitors.

8. The semiconductor device according to claim 1, wherein the ferroelectric film is provided on a top surface of the lower electrode or a top surface and a side surface of the lower electrode.

9. The semiconductor device according to claim 1, wherein the capacitor is a capacitor of a ferroelectric memory.

10. The semiconductor device according to claim 2, wherein the polysilazane-based coated insulating film further contains carbon.

11. The semiconductor device according to claim 2, wherein the plurality of capacitors has a 1 μm or less distance between neighboring capacitors.

12. The semiconductor device according to claim 2, further comprising a barrier film provided between each of the plurality of capacitors and the polysilazane-based coated insulating film and having resistance to reduction.

13. The semiconductor device according to claim 2, wherein the ferroelectric film is provided on a top surface of the lower electrode or a top surface and a side surface of the lower electrode.

14. The semiconductor device according to claim 2, wherein the capacitor is a capacitor of a ferroelectric memory.

15. The semiconductor device according to claim 3, wherein the capacitor is a capacitor of a ferroelectric memory.

16. The semiconductor device according to claim 4, wherein the capacitor is a capacitor of a ferroelectric memory.

17. A method of manufacturing a semiconductor device comprising:
forming a first conductive film, a ferroelectric film, and a second conductive film above a semiconductor substrate in sequence;
forming a plurality of capacitors by etching the second conductive film, the ferroelectric film, and the first conductive film, the plurality of capacitors comprising a plurality of upper electrodes each including the first conductive film, the ferroelectric film divided into a plurality of portions, and a plurality of lower electrodes each including the second conductive film; and
forming a polysilazane-based coated insulating film on the plurality of capacitors and between the plurality of capacitors so as to bury a gap between the plurality of capacitors by a coating method using a solution containing polysilazane.

18. The method of manufacturing a semiconductor device according to claim 17, further comprising:
heating the polysilazane-based coated insulating film in a nitrogen gas atmosphere after forming the polysilazane-based coated insulating film by the coating method.

19. A method of manufacturing a semiconductor device comprising:
forming a plurality of lower electrodes above a semiconductor substrate;
forming a ferroelectric film and a conductive film in sequence above the semiconductor substrate so as to cover top surfaces and side surfaces of the plurality of lower electrodes;
forming a polysilazane-based coated insulating film on the conductive film so as to bury a gap between the plurality of lower electrodes by a coating method using a solution containing polysilazane; and
forming a plurality of upper electrodes by etching the polysilazane-based coated insulating film and the conductive film.

20. The method of manufacturing a semiconductor device according to claim 19, further comprising:
heating the polysilazane-based coated insulating film in a nitrogen atmosphere after forming the polysilazane-based coated insulating film by the coating method.
